(19) United States
(12) Patent Application Publication
(10) Pub. No.: US 2008/0315892 A1
(43) Pub. Date: Dec. 25, 2008

(54) Methods and apparatus using one or more supernodes when testing for shorts between nodes of a circuit assembly

(76) Inventors: Kenneth P. Parker, Fort Collins, CO (US); Chris Richard Jacobsen, Fort Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/011,884

(22) Filed: Jan. 30, 2008

(30) Foreign Application Priority Data
Jun. 19, 2007 (CN) 200710108496.4

(51) Int. Cl. G01R 31/04

(52) U.S. Cl. 324/537

(57) ABSTRACT

A method of testing for shorts between nodes of a circuit assembly includes parsing circuit design data to identify positional data for nodes of a circuit assembly, and using the positional data to classify ones of the nodes as members of a supernode, where each member of the supernode is unlikely to be shorted to any other member of the supernode. Tests for shorts in a set of nodes that includes the supernode and a plurality of other nodes of the circuit assembly are then conducted, by iteratively i) stimulating a particular one of the set of nodes, and ii) while stimulating the particular node, grounding at least one other node in the set of nodes and monitoring a current flow through the particular node. When stimulating or grounding a supernode, all of the nodes that are members of the supernode are stimulated or grounded. If a current flow is detected through one of the stimulated nodes, the circuit assembly is indicated to be defective. Other embodiments are also disclosed.

### BACKGROUND

An in-circuit tester may execute a shorts test to search for unwanted connectivity (shorts) between the nodes of a printed circuit board (PCB). One way to do this is via a shorts test having a “search phase” and an “isolation phase”. During the search phase, each of a PCB's nodes is stimulated while grounding all other nodes. If a current flow is detected while stimulating a particular node, the isolation phase is entered. During the isolation phase, the particular node is stimulated again, but while grounding different subsets of the PCB's nodes. Often, the isolation phase implements a binary chop algorithm, where half of the previously grounded nodes are opened while half remain closed, and so on, until a pair of shorted nodes is isolated. Further details on such a shorts test can be found in Chapter 11 of the book edited by D. Gizopoulos, entitled “Electronic Testing Methodologies” (Springer-Vertag, 2005).

### BRIEF DESCRIPTION OF THE DRAWINGS

Illustrative embodiments of the invention are illustrated in the drawings, in which:

FIG. 1 illustrates a first exemplary method of testing for shorts between the nodes of a circuit assembly;

FIG. 2 illustrates a second exemplary method of testing for shorts between the nodes of a circuit assembly;

FIG. 3 illustrates an exemplary method for classifying nodes as members of one or more supernodes;

FIG. 4 illustrates a portion of an exemplary circuit assembly that may be tested for shorts using the methods shown in FIGS. 1-3;

FIG. 5 illustrates an exemplary method of testing for shorts in a set of nodes; and

FIG. 6 illustrates exemplary apparatus for carrying out the methods shown in FIGS. 1, 2, 3 & 5.

### DETAILED DESCRIPTION

As a preliminary manner, it is noted that, in the following description, like reference numbers appearing in different drawing figures refer to like elements/features. Often, therefore, like elements/features that appear in different drawing figures will not be described in detail with respect to each of the drawing figures.

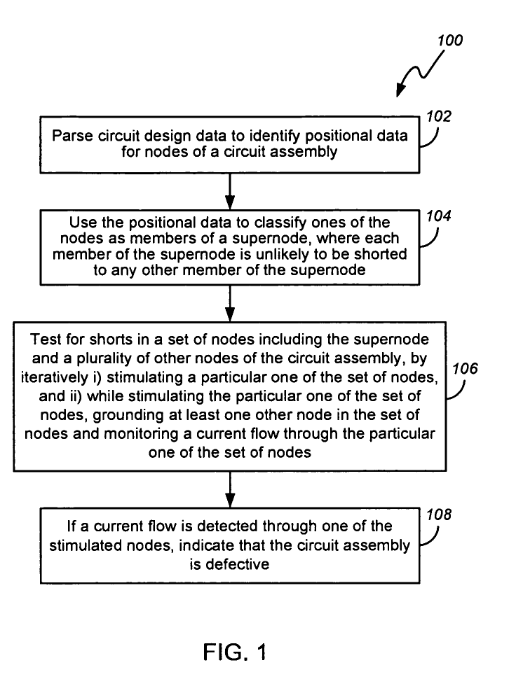

FIG. 1 illustrates an exemplary method 100 of testing for shorts between the nodes of a circuit assembly (such as a printed circuit board or Multi-Chip Module). In accord with the method 100, circuit design data is parsed to identify positional data for various nodes of a circuit assembly (at block 102). The positional data is then used to classify ones of the nodes as members of a supernode, where each member of the supernode is unlikely to be shorted to any other member of the supernode (at block 104). Shorts tests are then conducted for a set of nodes including the supernode and a plurality of other nodes of the circuit assembly (at block 106). The shorts tests are conducted by iteratively i) stimulating a particular one of the set of nodes, and ii) while stimulating a particular node, grounding at least one other node in the set of nodes and monitoring a current flow through the particular node. If a current flow is detected through one of the stimulated nodes, the circuit assembly is indicated to be defective (at block 108).

The method 100 can be advantageous in that it reduces the number of nodes that need to be tested for shorts. For example, if a circuit assembly has 500 nodes, but positional data for the circuit assembly shows that each of 100 nodes is unlikely to be shorted to any other of the 100 nodes, then these 100 nodes can be grouped into a single “supernode” for purposes of shorts testing, thereby reducing the number of nodes that need to be tested for shorts from 500 to 401. As a result, shorts testing throughput is increased.

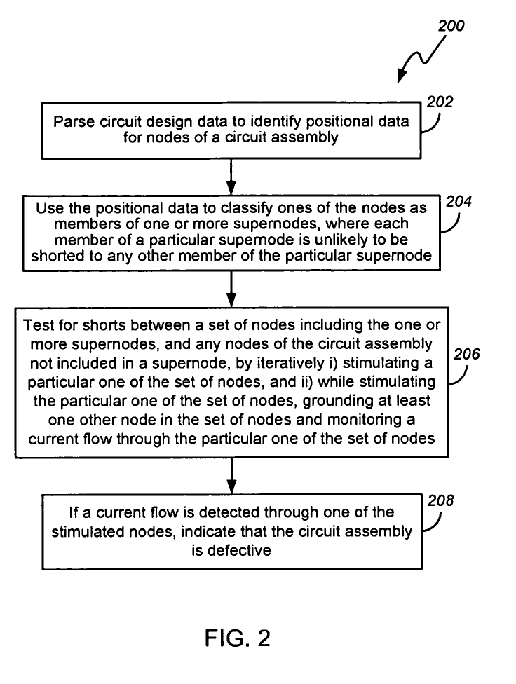

In one embodiment, the method 100 may be modified to classify different nodes as members of different supernodes, thereby providing a further reduction in the number of nodes that need to be tested for shorts. For example, and as shown in FIG. 2, the method 200 may comprise parsing circuit design data to identify positional data for nodes of a circuit assembly (at block 202). The positional data is then used to classify ones of the nodes as members of one or more supernodes, where each member of a particular supernode is unlikely to be shorted to any other member of the particular supernode (at block 204). Shorts tests are then conducted for a set of nodes including the one or more supernodes, and any nodes of the circuit assembly not included in a supernode, if any (at block 206). The shorts tests are conducted by iteratively i) stimulating a particular one of the set of nodes, and ii) while stimulating a particular node, grounding at least one other node in the set of nodes and monitoring a current flow through the particular node. If a current flow is detected through one of the stimulated nodes, the circuit assembly is indicated to be defective (at block 208).

Of note, the nodes that are stimulated or grounded by the methods 100 and 200 may include supernodes. If a supernode is stimulated, all of its member nodes are stimulated. If a supernode is grounded, all of its member nodes are grounded.

The positional data that is used to group nodes into a supernode can take various forms, including those of: coordinates of device pins that are coupled to the nodes; routing information for the electrical paths (e.g., signal, power or ground paths) that are coupled to the nodes; and information on component placements. In general, nodes that are physically distant from one another are unlikely to be shorted. However, the parameters for what is considered “physically distant” may vary, depending on factors such as: the process used to manufacture a circuit assembly; and the density of nodes on a circuit assembly.

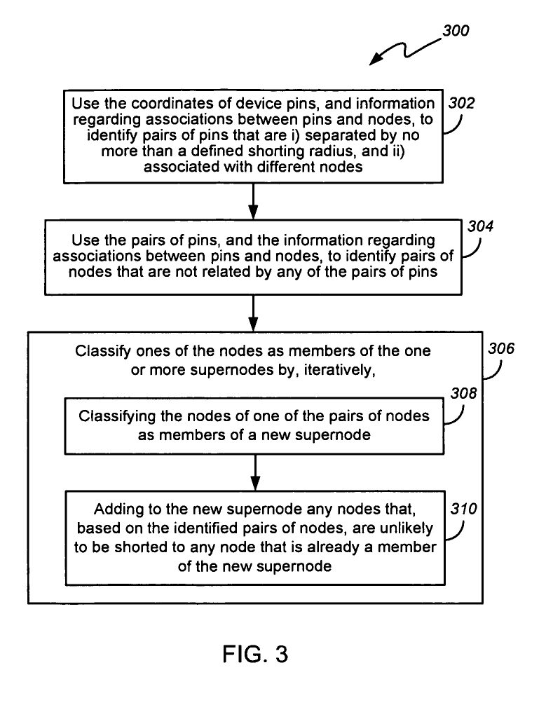

Typically, the most common causes of shorts are solder bridges between pins. Thus, in some embodiments of the methods 100, 200, the coordinates of device pins (i.e., positional data), and information regarding associations between pins and nodes, are used to classify nodes as members of one or more supernodes. Although there are many ways to do this, one way is shown in FIG. 3.

The method 300 (FIG. 3) begins with the identification of “pairs of pins” that are i) separated by no more than a defined shorting radius, but ii) associated with different nodes. See, block 302. The identified pin pairs therefore represent possible locations of shorts between nodes. The method 300 uses the identified pairs of pins, and information regarding associations between pins and nodes, to identify “pairs of nodes” that are not related by any of the pairs of pins. See, block 304. The pairs of nodes are thus pairs of nodes that are unlikely to be shorted.

Having identified pairs of nodes that are unlikely to be shorted, the method 300 classifies ones of a circuit assembly's nodes as members of one or more supernodes (at block 306). This is done by classifying the nodes of one of the pairs of nodes as members of a new supernode, and then adding to the new supernode any nodes that, based on the previously-identified “pairs of nodes”, are unlikely to be shorted to any node that is already a member of the new supernode. See, blocks 308, 310. The steps 308 and 310 may then be repeated on an iterative basis, until as many nodes as possible have been grouped into supernodes.

In one embodiment of the method 300 for classifying nodes as members of supernodes (FIG. 3), pairs of pins that have already been proven to be short-free are excluded from the identified pairs of pins. Thus, even when two pins are within a defined shorting radius, they may be excluded from the pairs of pins that are identified as possible short candidates when they have already been proven to be short-free.

In some embodiments of the method 300, the pair of nodes used to start the next new supernode may be chosen at random. However, in other cases, the initial pair of nodes may be chosen based on, for example: pre-knowledge that two nodes are physically distant from one another; or the frequency with which a particular node appears in “pairs of nodes” that are not related by pairs of physically close pins. Alternately, an algorithm may attempt to generate a plurality of potential supernodes having different members, and then select a set of supernodes that pulls the greatest number of a circuit assembly's nodes into supernodes—thereby attempting to reduce the number of nodes (including supernodes) that need to be tested for shorts to a minimum number of nodes.

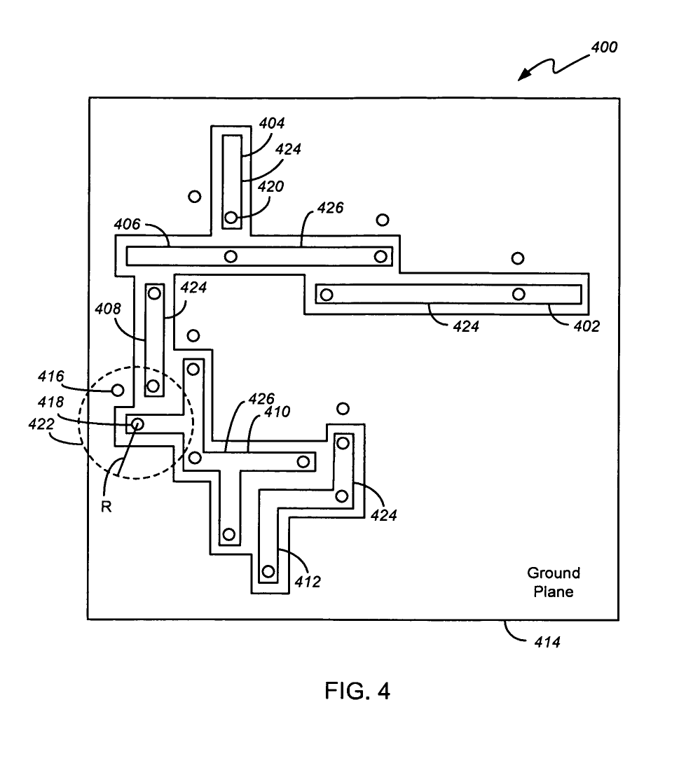

FIG. 4 illustrates a portion of an exemplary circuit assembly 400 having seven nodes 402, 404, 406, 408, 410, 412, 414 and fifteen pins (e.g, pins 416, 418, 420). In accord with the method 400, a circular window 422, having a shorting radius “R”, may be conceptually moved over the assembly 400 to determine which pairs of pins 416, 418, 420 are within the shorting radius from one another. For example, when the window 422 is centered on pin 418, it can be seen that pin 416 is within the shorting radius “R” from pin 418, but pin 420 is not. It is then determined which nodes the pins of the identified pin pairs belong to, and “pairs of nodes” that are not related by any of the “pairs of pins” are identified. In FIG. 4, the pairs of nodes that are not related by any pairs of pins are 402/404, 402/408, 402/410, 402/412, 404/408, 404/410, 404/412, 406/410, 406/412 and 408/412. From these pairs of nodes, and by way of example, two supernodes may be formed. A first supernode 424 may comprise nodes 402, 404, 408 and 412. A second supernode 426 may comprise nodes 406 and 410. The ground node 414, due to its pervasive nature, cannot be included in any supernode. Thus, for purposes of shorts testing under the method 200 (FIG. 2), the circuit assembly 400 can be considered to have three nodes 414, 424, 426.

Of note, FIG. 4 illustrates a two-dimensional array of nodes 402, 404, 406, 408, 410, 412, 414 and pins 416, 418, 420. However, the nodes and pins of many circuit assemblies may appear on one or both sides of a circuit assembly (e.g., on one or both sides of a printed circuit board). As a result, the positional data considered by the methods 100 and 200 (FIGS. 1 & 2) may not be limited to x-y positional data, but may include x-y-z positional data, as well as information regarding which nodes and pins of a circuit assembly extend from one side of a circuit assembly to the other.

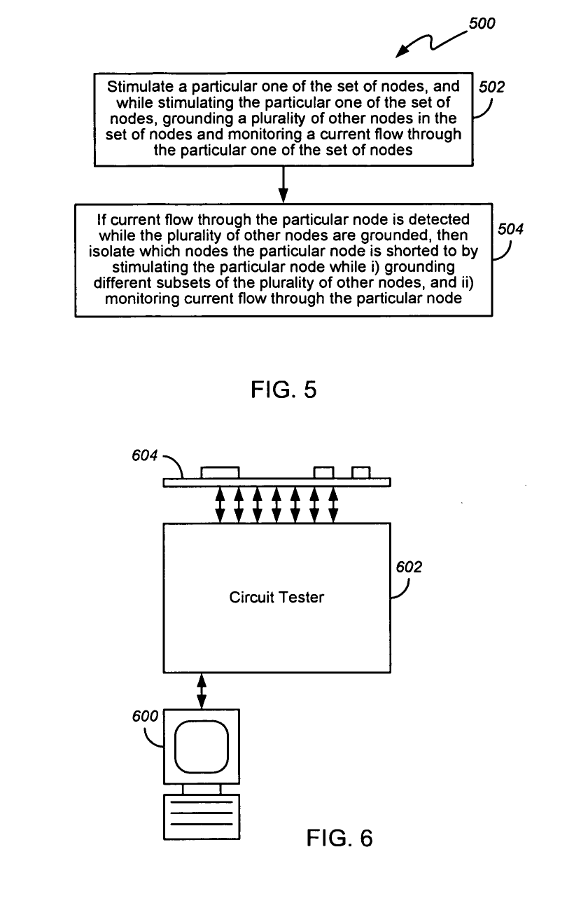

FIG. 5 illustrates an exemplary method 500 of testing for shorts in a set of nodes. The method 500 comprises a “search phase”, where ones of the nodes are iteratively stimulated, and while stimulating a particular one of the nodes, a plurality of other nodes in the set of nodes is grounded and a current flow through the particular one of the nodes is monitored (at block 502). Current flow through the particular node may be monitored, for example, by measuring the voltage across i) a known load resistor that is coupled in series with the particular node, or ii) a plurality of known load resistors that are coupled to each of a number of grounded nodes. If current flow through the particular node is detected while the plurality of other nodes are grounded, then the node(s) to which the particular node is shorted may be isolated during an “isolation phase”, by stimulating the particular node while i) grounding different subsets of the plurality of other nodes, and ii) monitoring current flow through the particular node (at block 504). Further details on such a shorts test can be found in Chapter 11 of the book edited by D. Gizopoulos, entitled “Electronic Testing Methodologies” (Springer-Verlag, 2005).

The methods 100 and 200 (FIGS. 1 & 2) may indicate that a circuit assembly is defective in various ways. For example, the methods 100, 200 could comprise notifying a user that a part is defective by displaying a warning on a display screen, or by triggering a warning light. Alternately, the methods 100, 200 could cause a robot to move a defective circuit assembly to a defective parts bin.

The methods 100, 200 may also indicate that a circuit assembly is defective by generating a report that includes more detailed data about where a short does or might exist. For example, a report could be generated that identifies i) which nodes in a set of nodes are shorted, and ii) for each pair of shorted nodes, the pairs of pins having one pin associated with each node of the pair of shorted nodes.

By way of example, the methods 100, 200 may be implemented by means of a computer system and a circuit tester that, together, are configured to perform the steps of the method 100 or method 200. In one embodiment, a computer system 600 (FIG. 6) is configured to parse circuit design data and identify the members (nodes) of one or more supernodes. A circuit tester 602, such as an in-circuit tester, is then configured to conduct shorts testing on a circuit assembly 604 under test and indicate whether the circuit assembly 604 is defective. Typically, the circuit tester 602 will be coupled to, and controlled by, the computer system 600. However, part or all of the circuit tester's functionality may be implemented by the computer system 600. For example, the computer system 600 may i) receive raw data that is indicative of a defective circuit assembly, and then ii) convey the indication via a display screen of the computer system 600, generate a report, or initiate an “isolation phase” of a shorts test method.

What is claimed is:

1. A method of testing for shorts in a circuit assembly, the method comprising:
parsing circuit design data to identify positional data for nodes of a circuit assembly;
using the positional data to classify ones of the nodes as members of a supernode, where each member of the supernode is unlikely to be shorted to any other member of the supernode;
testing for shorts in a set of nodes including the supernode and a plurality of other nodes of the circuit assembly, by iteratively i) stimulating a particular one of the set of nodes, and ii) while stimulating the particular one of the set of nodes, grounding at least one other node in the set of nodes and monitoring a current flow through the particular one of the set of nodes, wherein stimulating or grounding the supernode comprises stimulating or grounding all of the nodes that are members of the supernode; and
if a current flow is detected through one of the stimulated nodes, indicating that the circuit assembly is defective.

2. A method of testing for shorts in a circuit assembly, the method comprising:
parsing circuit design data to identify positional data for nodes of a circuit assembly;
using the positional data to classify ones of the nodes as members of one or more supernodes, where each member of a particular supernode is unlikely to be shorted to any other member of the particular supernode;
testing for shorts in a set of nodes including the one or more supernodes, and any nodes of the circuit assembly not included in a supernode, by iteratively i) stimulating a particular one of the set of nodes, and ii) while stimulating the particular one of the set of nodes, grounding at least one other node in the set of nodes and monitoring a current flow through the particular one of the set of nodes, wherein stimulating or grounding a supernode comprises stimulating or grounding all of the nodes that are members of the supernode; and
if a current flow is detected through one of the stimulated nodes, indicating that the circuit assembly is defective.

3. The method of claim 2, wherein the identified positional data comprises coordinates of device pins that are coupled to the nodes.

4. The method of claim 3, wherein using the positional data to classify ones of the nodes as members of the one or more supernodes comprises:
using the coordinates of the device pins, and information regarding associations between pins and nodes, to identify pairs of pins that are i) separated by no more than a defined shorting radius, and ii) associated with different nodes;
using the pairs of pins, and the information regarding associations between pins and nodes, to identify pairs of nodes that are not related by any of the pairs of pins; and
classifying ones of the nodes as members of the one or more supernodes by iteratively,
classifying the nodes of one of the pairs of nodes as members of a new supernode; and
adding to the new supernode any nodes that, based on the identified pairs of nodes, are unlikely to be shorted to any node that is already a member of the new supernode.

5. The method of claim 4, further comprising:
excluding from the pairs of pins, prior to identifying the pairs of nodes, any pair of pins that has already been proven to be short-free.

6. The method of claim 2, wherein:
testing for shorts in the set of nodes includes,
while stimulating the particular one of the set of nodes, grounding a plurality of other nodes in the set of nodes and monitoring a current flow through the particular one of the set of nodes; and
if current flow through the particular node is detected while the plurality of other nodes are grounded, then isolating which nodes the particular node is shorted to by stimulating the particular node while i) grounding different subsets of the plurality of other nodes, and ii) monitoring current flow through the particular node; and
indicating that the circuit assembly is defective includes identifying which nodes in the set of nodes are shorted.

7. The method of claim 6, wherein the identified positional data comprises coordinates of device pins that are coupled to the node, the method further comprising:
using the coordinates of the device pins, and information regarding associations between pins and nodes, to identify pairs of pins that are i) separated by no more than a defined shorting radius, and ii) associated with different nodes;
wherein testing for shorts in the set of includes,
while stimulating the particular one of the set of nodes, grounding a plurality of other nodes in the set of nodes and monitoring a current flow through the particular one of the set of nodes; and
if current flow through the particular node is detected while the plurality of other nodes are grounded, then isolating which nodes the particular node is shorted to by stimulating the particular node while i) grounding different subsets of the plurality of other nodes, and ii) monitoring current flow through the particular node; and
wherein indicating that the circuit assembly is defective includes, for each pair of shorted nodes, indicating the pairs of pins having one pin associated with each node of the pair of shorted nodes.

8. The method of claim 2, wherein the identified positional data comprises routing information for electrical paths that are coupled to the nodes.

9. The method of claim 2, wherein the identified positional data comprises information on component placements.

10. The method of claim 2, further comprising, using the positional data to classify ones of the nodes as members of multiple supernodes.

11. Apparatus for testing for shorts between nodes of a circuit assembly, the apparatus comprising:
a computer system configured to i) parse circuit design data to identify positional data for nodes of a circuit assembly, and ii) use the positional data to classify ones of the nodes as members of one or more supernodes, where each member of a particular supernode is unlikely to be shorted to any other member of the particular supernode; and
a circuit tester configured to,
test for shorts in a set of nodes including the one or more supernodes, and any nodes of the circuit assembly not included in a supernode, by iteratively i) stimulating a particular one of the set of nodes, and ii) while stimulating the particular one of the set of nodes, grounding at least one other node in the set of nodes and monitoring a current flow through the particular one of the set of nodes, wherein stimulating or grounding a supernode comprises stimulating or grounding all of the nodes that are members of the supernode; and
if a current flow is detected through one of the stimulated nodes, indicate that the circuit assembly is defective.

12. The apparatus of claim 11, wherein the identified positional data comprises coordinates of device pins that are coupled to the node.

13. The apparatus of claim 12, wherein the computer system is configured to use the positional data to classify ones of the nodes as members of the supernode by:
using the coordinates of the device pins, and information regarding associations between pins and nodes, to identify pairs of pins that are i) separated by no more than a defined shorting radius, and ii) associated with different nodes;
using the pairs of pins, and the information regarding associations between pins and nodes, to identify pairs of nodes that are not related by any of the pairs of pins; and
classifying ones of the nodes as members of the one or more supernodes by iteratively,
classifying the nodes of one of the pairs of nodes as members of a new supernode; and
adding to the new supernode any nodes that, based on the identified pairs of nodes, are unlikely to be shorted to any node that is already a member of the new supernode.

14. The apparatus of claim 13, wherein the computer system is configured to exclude from the pairs of pins, prior to identifying the pairs of nodes, any pair of pins that has already been proven to be short-free.

15. The apparatus of claim 11, wherein the circuit tester is configured to:
test for shorts in the set of nodes by,
while stimulating the particular one of the set of nodes, grounding a plurality of other nodes in the set of nodes and monitoring a current flow through the particular one of the set of nodes; and
if current flow through the particular node is detected while the plurality of other nodes are grounded, then isolating which nodes the particular node is shorted to by stimulating the particular node while i) grounding different subsets of the plurality of other nodes, and ii) monitoring current flow through the particular node; and
indicate that the circuit assembly is defective by identifying which nodes in the set of nodes are shorted.

16. The apparatus of claim 15, wherein the identified positional data comprises coordinates of device pins that are coupled to the node, and wherein:
the computer system is configured to use the coordinates of the device pins, and information regarding associations between pins and nodes, to identify pairs of pins that are i) separated by no more than a defined shorting radius, and ii) associated with different nodes;
the circuit tester is configured to test for shorts in the set of nodes by,
while stimulating the particular one of the set of nodes, grounding a plurality of other nodes in the set of nodes and monitoring a current flow through the particular one of the set of nodes; and
if current flow through the particular node is detected while the plurality of other nodes are grounded, then isolating which nodes the particular node is shorted to by stimulating the particular node while i) grounding different subsets of the plurality of other nodes, and ii) monitoring current flow through the particular node; and
the circuit tester is configured to indicate that the circuit assembly is defective by, for each pair of shorted nodes, indicating the pairs of pins having one pin associated with each node of the pair of shorted nodes.

17. The apparatus of claim 11, wherein the identified positional data comprises routing information for electrical paths that are coupled to the nodes.

18. The apparatus of claim 11, wherein the identified positional data comprises information on component placements.

19. The apparatus of claim 11, wherein the circuit tester is coupled to, and controlled by, the computer system.

20. The apparatus of claim 11, wherein at least part of the circuit tester's functionality is implemented by the computer system.

21. The apparatus of claim 11, wherein the computer system is configured to, upon the circuit tester indicating that the circuit assembly is defective, convey said indication via a display screen of the computer system.
